(19) United States
(12) Patent Application Publication
(10) Pub. No.: US 2024/0292644 A1
(43) Pub. Date: Aug. 29, 2024

(54) LIGHT-EMITTING DEVICE AND METHOD FOR USING QUANTUM DOT LEDS

(71) Applicants: ZHEJIANG UNIVERSITY, Hangzhou, Zhejiang (CN); Najing Technology Corporation Limited, Hangzhou, Zhejiang (CN)

(72) Inventors: Xiaogang PENG, Hangzhou, Zhejiang (CN); Xing LIN, Hangzhou, Zhejiang (CN); Xingliang DAI, Hangzhou, Zhejiang (CN)

(21) Appl. No.: 18/576,760

(22) PCT Filed: Jul. 12, 2022
(86) PCT No.: PCT/CN2022/105161

§ 371 Date: Jan. 5, 2024

(30) Foreign Application Priority Data
Jul. 15, 2021 (CN) 202110802082.1

(51) Int. Cl. H10K 50/115; H10K 101/60

(52) U.S. Cl. CPC H10K 50/115; H10K 2101/60

(57) ABSTRACT

A light-emitting device and method for using quantum dot LEDs are provided in the present application. The light-emitting device includes at least one quantum dot LED, wherein the quantum dot LED includes a first electrode, an electron transport layer, a quantum dot layer, a hole transport layer, and a second electrode which are sequentially stacked; a fluorescence quantum yield of quantum dots in the quantum dot layer is equal to or greater than 50%; a ratio of an average photon voltage to an operating voltage of the quantum dot LED is equal to or greater than 1; electroluminescence of the quantum dot LED includes thermoelectrically-assisted up-conversion luminescence. The quantum dot LED can achieve higher external power conversion efficiency in the light-emitting device.

### CROSS-REFERENCE

This application is a national phase entry under 35 U.S.C. § 371 of International Patent Application PCT/CN2022/105161, filed Jul. 12, 2022, designating the United States of America and published as International Patent Publication WO 2023/284728 A1 on Jan. 19, 2023, which claims the benefit under Article 8 of the Patent Cooperation Treaty to Chinese Patent Application Serial No. 202110802082.1, filed on Jul. 15, 2021, the disclosure of which is hereby incorporated herein in its entirety by this reference.

### TECHNICAL FIELD

The present application relates to the technical field of quantum dot LEDs, and in particular to a light-emitting device and a method for using quantum dot LEDs.

### BACKGROUND

Thermoelectric-pumped LEDs (TEP-LEDs) can achieve power conversion efficiencies greater than 100% under the influence of sub-bandgap electrical power and Peltier heat. However, obtaining cost-effective and highly efficient LEDs is challenging due to the high cost of epitaxially grown III-V semiconductor light-emitting chips and the decrease in efficiency at low carrier densities. The III-V chips can only reduce lattice defects by continually optimizing expensive and intricate epitaxial growth techniques, thereby improving efficiency in devices. Hence, there is a need for a low-cost, high-efficiency TEP-LED design and preparation method.

### SUMMARY

A light-emitting device is provided according to a first aspect of the present application. The light-emitting device includes at least one quantum dot LED, wherein the quantum dot LED includes a first electrode, an electron transport layer, a quantum dot layer, a hole transport layer, and a second electrode which are sequentially stacked; a fluorescence quantum yield of quantum dots in the quantum dot layer is equal to or greater than 50%; a ratio of an average photon voltage to an operating voltage of the quantum dot LED is equal to or greater than 1; electroluminescence of the quantum dot LED includes thermoelectrically-assisted up-conversion luminescence.

A method for using quantum dot LEDs is provided according to a second aspect of the present application, the quantum dot LED includes a first electrode, an electron transport layer, a quantum dot layer, a hole transport layer, and a second electrode which are sequentially stacked; a fluorescence quantum yield of quantum dots in the quantum dot layer is equal to or greater than 85%, making a ratio of an average photon voltage to an operating voltage of each of the quantum dot LEDs equal to or greater than 1; electroluminescence of the quantum dot LED includes thermoelectrically-assisted up-conversion luminescence.

According to the light-emitting device and method for using quantum dot LEDs mentioned above, by setting the ratio relationship between the operating voltage and the average photon voltage, quantum dot LEDs maintain high power conversion efficiency, thereby reducing power consumption. Furthermore, high IQE quantum dot LEDs (QLED for short) can be prepared by using cost-effective solution processing techniques and chemical materials, making the cost for manufacturing large-area TEP-QLED devices very low.

### BRIEF DESCRIPTION OF THE DRAWINGS

The accompanying drawings constituting a part of the present application are intended to provide further understanding of the present application. The exemplary embodiments of the present application and illustrations thereof are used to explain the present application and do not constitute an undue limitation to the present application. In the accompanying drawings:

FIG. 1 shows a schematic structural diagram of a quantum dot LED according to one embodiment of the present application.

FIG. 2 shows a schematic structural diagram of a device for characterizing temperature-related performance.

FIG. 3 shows the photoluminescence decay kinetics curves of CdSe/CdS core/shell quantum dot ensemble used in Example 1, with the inset being a TEM image thereof.

FIG. 4 shows the EQE/EPE and luminance as a function of operating voltage for the QLED device in Example 1.

FIG. 5 shows the electroluminescence intensity variation of the QLED device in Example 1 at different operating voltages.

FIG. 6 shows the relationship between the EQE and the operating voltage of the QLED device obtained in Example 1 at various temperatures.

FIG. 7 shows the relationship between the operating voltage and the luminance of the QLED device obtained in Example 1 at different temperatures. Markers in FIG. 7 represent the same meaning as those in FIG. 8.

FIG. 8 shows the relationship between the operating voltage and the current density of the QLED device obtained in Example 1 at different temperatures.

FIG. 9 shows the relationship between the temperature and the operating voltage of the QLED device obtained in Example 1 at a particular EQE.

FIG. 10 shows the relationship between the IQE and the V/Vp of the QLED device obtained in Example 1 at different temperatures.

FIG. 11 shows EQE curves of the QLED devices obtained in Examples 2 to 4 at different operating voltages.

FIG. 12 shows EPE curves of the QLED devices obtained in Examples 2 to 4 at different luminance.

### DETAILED DESCRIPTION

It should be noted that the following detailed descriptions are all exemplary and are intended to provide further explanation of the present application. Unless otherwise stated, all technical and scientific terms used herein have the same meanings as that commonly understood by those of ordinary skill in the art to which the present application belongs.

The terms “include”, “contain”, and any other variants in the specification and claims of the present application mean to cover the non-exclusive inclusion, for example, a process, method, system, product, or device that includes a list of steps or units is not necessarily limited to those steps or units which are clearly listed, but may include other steps or units which are not expressly listed or inherent to such a process, method, system, product, or device. The terms “first”, “second”, and so on are intended to distinguish between similar objects but do not necessarily describe a specific order or sequence. The symbol “˜” before a specific numerical value represents “approximately”. “Approximately” encompasses the stated value and implies an acceptable range of deviation from the specific value as determined by such as those of ordinary skill in the art in view of measurement in question and errors associated with the measurement of the particular quantity (i.e., the limitations of the measurement system). For example, “approximately” may mean a deviation within one or more standard deviations or within a range of +10% or +5%. Improving the external power conversion efficiency (EPE) of LEDs can reduce energy costs, mitigate heat dissipation issues, and extend the service life of the light-emitting devices. For LED applications in the industry, operating voltage V (drive voltage) greater than Vp (average photon voltage) allows for maximizing absolute energy output, reducing the area of expensive light-emitting chips, and avoiding a decrease in internal quantum efficiency (IQE) at low current densities. The electric-to-optical power conversion efficiency (also known as EPE) of LEDs consists of three components: IQE, Vp/V, and Light Extraction Efficiency (LEE):

EPE=IQE×Vp/V×LEE=IPE×LEE (1),
wherein V represents the drive voltage, and Vp is defined as the ratio between the average photon energy (hv) and the elementary charge (q), i.e., Vp represents the average photon voltage. For example, if the light from the luminescent center of the material is at 620 nm, corresponding to a photon energy of 2 eV, the photon voltage would be 2 V. h represents the Planck constant, and v represents the frequency of the light wave. LEE is dependent on the optical design of the device. Therefore, the high EPE of LEDs essentially relies on the internal power efficiency (IPE) of the device, and IPE in turn is associated with IQE and Vp/V Simultaneously achieving high IQE and low operating voltage is crucial in pursuing high EPE. For bulk-sized semiconductor crystals, IQE can be calculated using the following formula:

$$IQE = \text{?} , \qquad ( 2 )$$

$$\text{?} \text{indicates text missing or illegible when filed}$$

wherein n represents the carrier density in the active region, A is the indirect recombination (also known as Shockley-Read-Hall) constant, B is the radiative constant, and C is the Auger recombination constant. Formula (2) indicates that IQE sharply decreases at low carrier densities. Indirect and Auger recombinations are unavoidable. Based on the above formula, there are two solutions for LED devices based on epitaxial semiconductor materials to implement TEP-LED. The first solution involves setting the operating voltage significantly lower than k_{g}T/q, wherein kAils the Boltzmann constant, and T is the absolute temperature. Within this range, IQE does not depend on carder concentration and remains a constant close to zero. Photon energy primarily comes from Peltier heat, but the drawback is that the device's luminance is very low in the order of picowatts. The second solution is achieved through the design of asymmetric potential barrier difference to enable an excess of carriers in the light-emitting region at low voltages. In this case. IQE is a constant close to 1, which imposes stringent requirements on controlling the concentration of defect recombination centers of the material.

Colloidal quantum dots (QDs) are a type of solution-processable semiconductor nanocrystals. Since their size is typically smaller than the free diffusion length of impurities at higher synthesis temperatures, QDs exhibit a three-dimensional carrier quantum confinement effect. Quantum dots generally have a fluorescence quantum yield equal to or greater than 50%, making them highly advantageous for TEP-LED applications. Furthermore, QLEDs (quantum dot light-emitting diodes) with high IQE can be prepared using cost-effective solution processing techniques and chemical-grade materials, which means that the manufacturing cost of large-area devices can be reduced.

Based on the above analysis, the present application provides a light-emitting device. The light-emitting device comprises at least one quantum dot LED. The quantum dot LED comprises a first electrode, an electron transport layer, a quantum dot layer; a hole transport layer, and a second electrode which are sequentially stacked. The fluorescence quantum yield of the quantum dots in the quantum dot layer is equal to or greater than 50%. The ratio of the average photon voltage to the operating voltage of the quantum dot LED is equal to or greater than 1. Electroluminescence of the quantum dot LED comprises thermoelectrically-assisted up-conversion luminescence. The average photon voltage is calculated based on a theoretical formula. This method can enhance the external power conversion efficiency (EPE) of the quantum dot LED, thereby achieving energy saving and emission reduction.

In the present application, the quantum dot LED is also referred to as QLED. A QLED with thermoelectrically-assisted up-conversion luminescence is abbreviated as TEP-QLED. Thermoelectrically-assisted up-conversion luminescence is a result of the operation of the aforementioned light-emitting device. The definition of “thermoelectrically-assisted” refers to the definition of traditional epitaxial semiconductor LEDs. The principle of thermoelectrically-assisted up-conversion luminescence is that the voltage source performs work on the carriers, which simultaneously absorb lattice thermal energy during diffusion and emit band-edge photons. The energy of the band-edge photons can be significantly greater than the input electrical energy and is, in fact, derived from lattice thermal energy. Therefore, thermoelectrically-assisted up-conversion luminescence may reduce the operating temperature of the light-emitting device.

In some embodiments, the operating voltage equals the average photon voltage, and over 50% of the electroluminescence in the quantum dot LED is thermoelectrically-assisted up-conversion luminescence. In some embodiments where the operating voltage is lower than the average photon voltage, this proportion increases.

The choice of the quantum dot LED's operating voltage is related to the average photon energy of the quantum dots used. In some embodiments, the quantum dot layer comprises red quantum dots, the operating voltage is 1.86 V, and over 90% of the electroluminescence in the quantum dot LED is thermoelectrically-assisted up-conversion luminescence.

In some embodiments, the quantum dots in the quantum dot layer are free of internal lattice defects, and the quantum dots have no surface trap luminescence, presenting non-blinking fluorescence. The quantum dots within their lattice are defect-free, eliminating defect-related indirect recombination. The surface of the quantum dot is passivated by a specific ligand, removing most of the surface traps. Therefore, a fluorescence quantum yield of equal to or greater than 90% can be achieved, even achieving 100%.

In some embodiments, the electron transport layer of the quantum dot LED comprises one or more layers, and the hole transport layer comprises one or more layers. An electron injection layer may be further comprised between the electron transport layer and the first electrode, and a hole injection layer may be further comprised between the hole transport layer and the second electrode. In some embodiments, the structure of the quantum dot LED may further comprise other auxiliary functional layers, such as carrier blocking layers, interface layers, etc.

In some embodiments, the fluorescence quantum yield of the quantum dots in the quantum dot layer is equal to or greater than 85%, or the fluorescence quantum yield of the quantum dots in the quantum dot layer is equal to or greater than 90%, or the fluorescence quantum yield of the quantum dots in the quantum dot layer is equal to or greater than 95%. A higher fluorescence quantum yield of the quantum dots is advantageous for improving EPE.

In some embodiments, the quantum dot layer has a thickness of 1 to 2 monolayers of quantum dots. Maintaining a high IQE while reducing the operating voltage is crucial for achieving a high IPE in QLEDs. The emission layer of a traditional QLED is typically composed of a densely-packed quantum dot film, approximately 30 nm thick, which is about 3 to 4 monolayers of quantum dots. The carrier hopping between adjacent quantum dots and the low mobility of the carrier transport layer consume electric potential and reduce current density and emission intensity. On the other hand, reducing the thickness of the quantum dot layer to sub-monolayer levels increases the risk of leakage current, which can impede the achievement of high IQE. Limiting the thickness of the emission layer to 1 to 2 monolayers of quantum dots can eliminate unnecessary voltage losses. A monolayer of quantum dots represents a state where the quantum dots are not stacked, so its thickness is approximately equal to the average size of the quantum dots. The average size of the quantum dots can be 1 nm to 20 nm, or 5 nm to 50 nm.

In some embodiments, the full-width at half maximum (FWHM) of the quantum dots in the quantum dot layer is equal to or less than 80 meV.

In some embodiments, in the quantum dot LED structure, the electron transport layer comprises a ZnMgO nanocrystal layer, and the hole transport layer comprises a PVK layer, a Poly-TPD layer, and a PEDOT: PSS layer which are sequentially arranged. The first electrode is a silver electrode, and the second electrode is an ITO electrode. Other better materials and/or structures may also be employed for the quantum dot LED to enhance the light-emitting efficiency, and the options are not limited to those mentioned.

In some embodiments, the quantum dots in the quantum dot layer are CdSe/CdS core-shell quantum dots or CdSe/CdSeS/ZnS core-shell quantum dots. The kind of quantum dots is not limited, and other quantum dots with high electroluminescence efficiency can be selected as well. The quantum dots may also be cadmium-free quantum dots or doped quantum dots, and any quantum dots with high-quality luminescent properties can be tried.

In some embodiments, the ratio of the average photon voltage to the operating voltage is equal to or less than 2. In some embodiments, the ratio of the average photon voltage to the operating voltage is equal to or less than 1.2. In some embodiments, the ratio of the average photon voltage to the operating voltage is equal to or less than 1.15. Within the previously mentioned range of ratios, QLEDs with higher EPE can be prepared using existing quantum dot materials and processes.

In some embodiments, the operating temperature of the quantum dot LED is −40° C. to 50° C., and the external quantum efficiency (EQE) of the quantum dot LED increases as the operating temperature rises.

In some embodiments, the operating current density of the quantum dot LED is less than 1 mA/cm², or 0.5 mA/cm² to 0.6 mA/cm². With improvements in existing materials and processes, its operating current density can be further increased.

In some embodiments, the operating voltage of the quantum dot LED is lower than the average photon voltage by 0.05 V to 0.2 V.

In some embodiments, under operating conditions at 100 cd/m², the internal power efficiency (IPE) of the quantum dot LED is equal to or greater than 90%. With improvements in existing materials and processes, IPE can be further increased, or can exceed 100%.

In some embodiments, the external power conversion efficiency (EPE) of the quantum dot LED is equal to or greater than 15% or equal to or greater than 18%. In some embodiments, the external power conversion efficiency (EPE) of the quantum dot LED is equal to or greater than 20%. In some embodiments, the quantum dot LED is not provided with a light extraction structure, and the external power conversion efficiency of the quantum dot LED is equal to or greater than 20%. In some embodiments, the quantum dot LED is internally provided with a light extraction structure. In some embodiments, the quantum dot LED is externally provided with a light extraction structure, resulting in an external power conversion efficiency of the light-emitting device greater than the external power conversion efficiency of the quantum dot LED, i.e., greater than 20%.

In some embodiments, the internal quantum efficiency (IQE) of the quantum dot LED is equal to or greater than 90%.

In some embodiments, the quantum dot LED is prepared using a solution-based method to achieve cost-effective preparation. Solution-based methods include ink-jet printing, coating method, etc.

In some embodiments, the light-emitting device mentioned above is an illumination device or a display device. The quantum dot LED comprises quantum dot LEDs with various emitting wave bands. The operating voltage for each of the quantum dot LEDs is independently controlled, such that the ratio of the average photon voltage to the corresponding operating voltage of each of the quantum dot LEDs is equal to or greater than 1.

In some embodiments, the types of quantum dot LEDs mentioned above comprise red quantum dot LEDs, green quantum dot LEDs, blue quantum dot LEDs, or combinations thereof.

According to a second aspect of the present application, a method for using a quantum dot LED is provided. The quantum dot LED comprises a first electrode, an electron transport layer, a quantum dot layer, a hole transport layer, and a second electrode which are sequentially stacked. The fluorescence quantum yield of the quantum dots in the quantum dot layer is equal to or greater than 85%, making the ratio of the average photon voltage to the operating voltage of each quantum dot LED equal to or greater than 1. Electroluminescence of the quantum dot LED comprises thermoelectrically-assisted up-conversion luminescence. The operating voltage mentioned above is set artificially based on the average photon voltage. In some embodiments, the method for using the quantum dot LED mentioned above can achieve an external power conversion efficiency (EPE) equal to or greater than 15%, or equal to or greater than 18%, or equal to or greater than 20%.

In some embodiments, the ratio of the average photon voltage to the operating voltage is equal to or less than 2. In some embodiments, the ratio of the average photon voltage to the operating voltage is equal to or less than 1.2. In some embodiments, the ratio of the average photon voltage to the operating voltage is equal to or less than 1.15.

In some embodiments, the fluorescence quantum yield of the quantum dots in the quantum dot layer is equal to or greater than 85%, or the fluorescence quantum yield of the quantum dots in the quantum dot layer is equal to or greater than 90%, or the fluorescence quantum yield of the quantum dots in the quantum dot layer is equal to or greater than 95%. A higher fluorescence quantum yield is advantageous for improving EPE.

In some embodiments, the operating temperature of the quantum dot LED is −40° C. to 120° C. In some embodiments, the operating temperature of the quantum dot LED is −40° C. to 120° C. In theory, the higher the temperature, the more significant the thermally-assisted up-conversion luminescence, but the upper limit of the operating temperature needs to take into account the stability of the various layers of materials of the quantum dot LED. A wide range of operating temperatures is highly advantageous for the applications of related products. In some embodiments, the operating temperature of the quantum dot LED is −40° C. to 50° C., and the external quantum efficiency (EQE) of the quantum dot LED increases as the operating temperature rises.

The beneficial effects of the present invention are further explained through the embodiments below.

### Example 1

### Synthesis Method of High-Quality CdSe/CdS Core-Shell Quantum Dot Ensemble

Myristic acid (98%), stearic acid (>90%), lauric acid (99.5%), cadmium oxide (CdO, 99.998%), selenium power (Se, 200 mesh, 99.999%), 1-octadecene (ODE, 90%), oleic acid (99% or 90%), sulfur powder (S, 99.98%), and oleylamine (>98%) were purchased from either Aldrich or Alfa-Aesar. Tributylphosphine (TBP) was purchased from Acros. Cyclopentane (>98.0%) were purchased from TCI. Toluene, methanol, chloroform, acetone, and acetonitrile were obtained from Sinopharm Reagents. All chemicals were used directly without any further purification unless otherwise stated.

Synthesis of CdSe Core Quantum Dots (with a first absorption peak at 570 nm) The selenium suspension was prepared by dispersing 0.15 mmol of selenium powder in 3 mL of ODE and being sonicated for 5 min. In a typical synthesis, CdO (0.2 mmol) and myristic acid (0.45 mmol) were loaded into a 25 ml three-necked flask, and then 4 mL of ODE was added. After stirring, the mixture was bubbled with argon for 10 min, and then heated to 290° C. to obtain a colorless solution.

The mixture was cooled to 250° C., and then 1 mL of selenium suspension was rapidly injected into the flask, further lowering the temperature to 220° C. The reaction temperature was maintained at 240° C. for further growth. After 5 min of growth, another injection syringe of selenium suspension (with 0.3 mmol of selenium powder dispersed in 2 mL of ODE and 1 mL of oleic acid) was used to add selenium suspension dropwise at a rate of 0.015 mL/min into the reaction flask. The injection syringe was shaken every 5 min to keep the suspension uniform. After adding one dose of selenium suspension, let the reaction solution react for 5 min. The reaction was cycled, with each reaction cycle having one dose of selenium suspension added, followed by a 5-min reaction, until CdSe quantum dots with the desired size were obtained.

### Purification of CdSe Core Quantum Dots

For the purification of CdSe core quantum dots, a mixed solution of acetone, chloroform, and methanol (in a 1:1:1 volume ratio) was prepared as a precipitant solution. The crude reaction solution (1 mL to 1.5 mL) and the precipitant solution (2 mL) were consecutively added to a 4 mL vial. After heating to ˜50° C., the vial was immediately centrifuged at 4000 rpm for 20 s. The supernatant was rapidly removed. The quantum dot precipitate was then dissolved in ˜0.5 mL of toluene, and another 2 mL of the precipitant solution was added for another round of purification. This purification process was repeated two more times. In the examples, the symbol “˜” before a numerical value represents “approximately”.

### Epitaxial Growth of CdS for Preparing CdSe/CdS Core-Shell Quantum Dots

S-ODE Solution: Sulfur powder (1 mmol) was dissolved in ODE (10 mL) and prepared through sonication. In a typical synthesis, CdO (0.5 mmol) and myristic acid (1.1 mmol) (or 1.15 mmol of lauric acid) were loaded into a 25 mL three-necked flask containing 3.5 mL of ODE. After stirring, the mixture was bubbled with argon for 10 min, and then heated to 290° C. to become a colorless solution. The mixture was then cooled to below 150° C. Purified CdSe core quantum dots were dissolved in ODE and injected into the reaction solution. The new mixture was heated to 250° C. and purged with argon. A dose of S-ODE solution was loaded into an injection syringe and added dropwise to the reaction flask at a rate of 0.015 ml/min. After adding a dose of S-ODE, let the reaction solution react for 2 min. A dose of oleic acid (0.2 mmol) was added to the flask at a rate of 0.2 mL/min, followed by stirring for 2 min. For the second cycle, the reaction duration was within 5 min after the addition of S-ODE and oleic acid. In this reaction cycle, a dose of S-ODE was added, followed by a 5-min reaction, then a dose of oleic acid was added, and the reaction continued for 5 min until the desired CdSe/CdS core-shell quantum dots were obtained. When high-quality CdSe/CdS core-shell quantum dots had a shell thickness of 7 to 8 monolayers (with a photoluminescence peak at ˜630 nm), the molar ratio of the total amount of oleic acid to myristic acid (or lauric acid) is 3:1 to 4:1.

### Ligand Exchange

A mixture of 1 mL of ODE and 2 mL of oleylamine was placed in a three-necked flask and heated to 200° C. under an argon atmosphere. 0.1 mL of TBP was injected into the mixture. The core-shell quantum dots with purified carboxylate ligands were dissolved in 0.3 mL of ODE and then injected into the flask. The reaction mixture was maintained at 200° C. for 5 min to 10 min to complete the ligand exchange.

The resulting quantum dots had a PL peak wavelength of 632.6 nm, an FWHM of 30 nm, and an average size of 10 nm. These quantum dots were used for all subsequent tests and applications.

Preparation of Zn_{0.9}Mg_{0.1}O

A DMSO solution (30 mL) of zinc acetate hydrate (2.7 mmol) and magnesium acetate hydrate (0.3 mmol) mixed dropwise with an ethanol solution (10 mL) of TMAH (5 mmol). The mixture was stirred for 1 hour in a water bath at 50° C. under ambient conditions. The resulting Zn_{0.9}Mg_{0.1}O nanocrystals were precipitated by adding ethyl acetate, further purified by dispersing/precipitating twice using the combination of ethanol/ethyl acetate, and re-dispersed in ethanol.

### Preparation of CdSe/CdS QLED Device

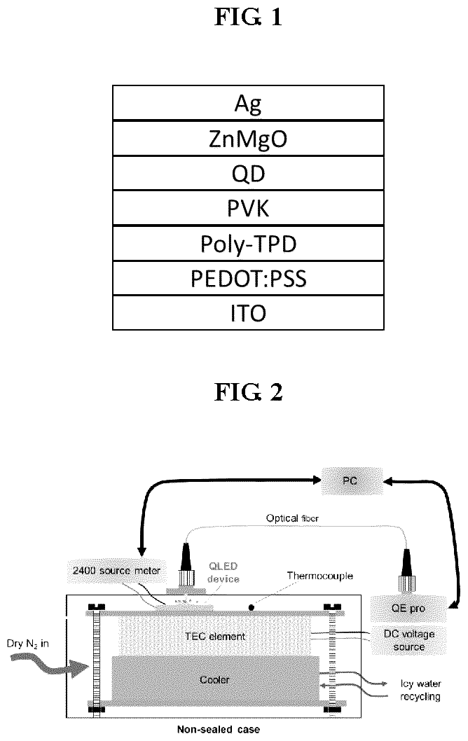

The ITO-coated glass substrates (˜40 Ω per square in sheet resistance) were cleaned with acetone, deionized water, and ethanol in an ultrasonic bath. Oxygen plasma treatment was undertaken for 8 min using an ultraviolet ozone cleaner (Harrick Plasma, PDC-32G-2). A PEDOT:PSS solution (Baytron PVP A1 4083) was spin-coated onto the substrates at 3,500 r.p.m. for 45 s and baked at 150° C. for 30 min. The PEDOT:PSS-coated substrates were subjected to an oxygen plasma for 4 min and then transferred to a nitrogen-filled glove box (O₂<1 ppm, H₂O<1 ppm) for subsequent processes. Poly-TPD solutions (in chlorobenzene, 8 mg mL⁻¹) were spin-coated at 2,000 r.p.m. for 45 s and baked at 150° C. for 30 min. PVK solutions (in m-xylene, 8 mg mL⁻¹) were spin-coated at 2,000 r.p.m. for 45 s, followed by baking at 150° C. for 30 min. QD solutions (in octane, ˜12 mg mL¹) and Zn_{0.9}Mg_{0.1}O nanocrystals (in ethanol, ˜30 mg/mL) were layer-by-layer spin-coated onto the substrates at 2,000 r.p.m. for 45 s. Next, Ag electrodes (100 nm) were deposited by a thermal evaporation system (Trovato 300C) under a high vacuum (˜2×10⁻⁷ torr). See FIG. 1 for TEP QLED structure.

### Characterization Methods

Devices were characterized under ambient conditions. The current density-luminance-voltage (J-L-V) characteristics of the TEP-QLEDs were measured on a system consisting of a Keithley 2400 source meter and a QE-Pro spectrometer coupled with an integration sphere (Ocean Insight FOIS-1). The devices were swept from zero bias to forward bias with a scanning rate of 0.01 V s⁻¹.

For the characterizations at the very-low bias range, the electroluminescence intensity was detected by an avalanche photodetector (PicoQuant τ-SPAD APD) through a multimode fiber (core diameter 62.5 um). Photon counts were recorded by a time-correlated single-photon counting module (Becker & Hickl DPC-230).

To obtain absolute luminance, photon counts recorded by APD were calibrated by a factor to give the same luminance in the 1.5-1.6 V voltage range as the one acquired with integration sphere method.

FIG. 2 shows a schematic structural diagram of a device for characterizing temperature-related performance. After characterization at room-temperature, the device was transferred onto a temperature-controlled metal holder. The metal holder is attached to a thermoelectric cooling (TEC) element whose bottom side temperature was kept at 0° C. by icy-water recycling system. To avoid condensation and freeze of moisture which would scatter out-light, the setup was put into an imperfectly-sealed box with dry N₂ filling the volume. Optical intensity acquired by QE-pro spectrometer were corrected by a factor to give the same luminance at room temperature as the one acquired with integration sphere method mentioned above. The same correction factor was used for measurement under different temperatures. The voltage source driving TEC element was set at different target values to reach desired holder temperatures. Wait at least 5 min before acquiring data for each test point to let the temperature stabilize.

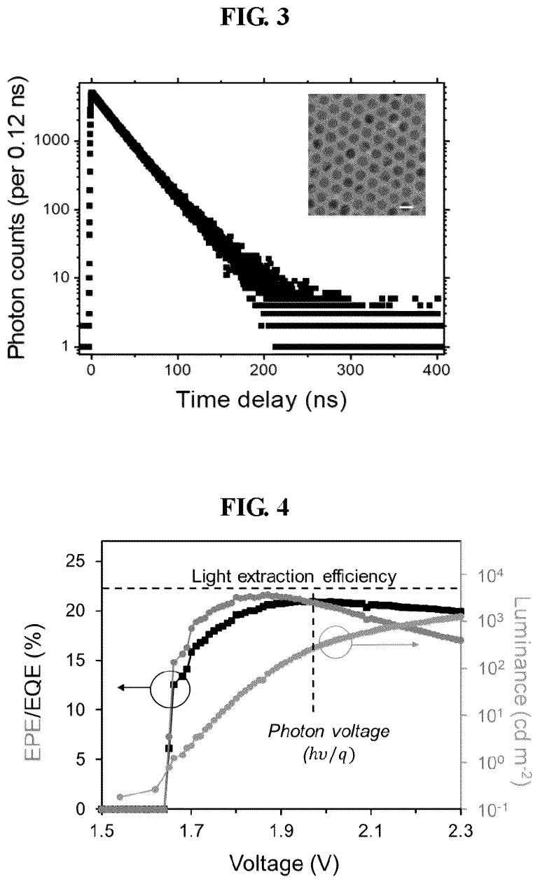

The CdSe/CdS core-shell quantum dots used for preparing TEP-QLED have excellent photoluminescence properties, i.e., 92% photoluminescence quantum efficiency, single-exponential photoluminescence decay kinetics, and stable emission, as shown in FIG. 3. The QLED device was tested and had the following thickness: ZnMgO layer 60 nm, quantum dot layer 10 nm, Poly-TPD+PVK layer 30 nm, PEDOT layer 40 nm, and ITO coating 100 nm.

FIG. 4 shows the variation in EPE, EQE, and luminance of TEP-QLED in Example 1 at different operating voltages. The crossover point of the EPE and EQE curves corresponds to the EL energy peak (1.96 eV). Specifically, at a luminance relevant to the display field (100 cd/m²), the operating voltage was 1.89 V, reaching a Vp/V value of 104%. Therefore, EPE (21.5%) exceeded EQE (20.5%). The light extraction efficiency of the device was 23% as measured by the literature method (Neyts, K. A. Simulation of light emission from thin-film microcavities. J. Opt. Soc. Am. A 15 (1998), Sullivan, K. G. & Hall, D. G. Enhancement and inhibition of electromagnetic radiation in plane-layered media IPlane-wave spectrum approach to modeling classical effects. J. Opt. Soc. Am. B 14 (1997)). Therefore, the peak IPE of the device was close to 100% (93.5%), and the peak IQE was 91%. These results all demonstrated a high-efficiency TEP-LED.

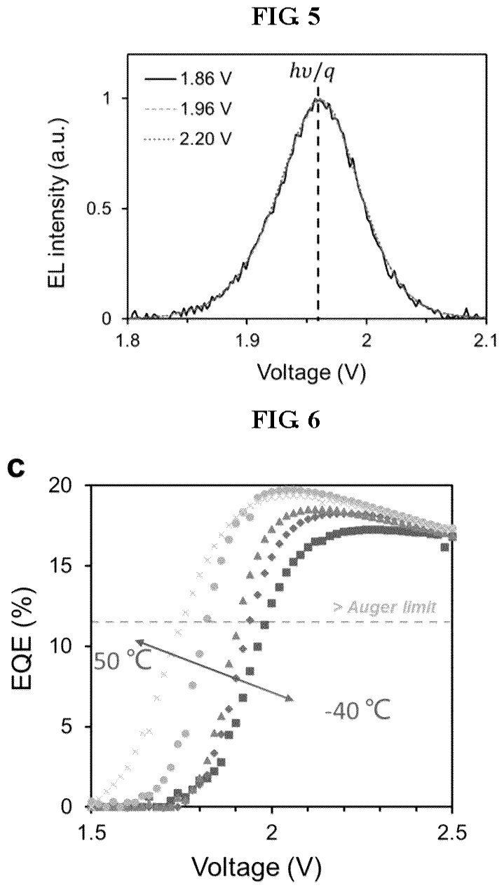

As shown in FIG. 5, the normalized electroluminescent spectra of the device in Example 1 at 1.86 V, 1.96 V (V, =hv/q=1.96 V), and 2.20 V overlapped, eliminating low-energy defect emission states. At 1.96 eV, the electroluminescent peak was narrow and symmetrical, with almost all electroluminescence obtained at 1.86 V, and half of the electroluminescence obtained at 1.96 V was Peltier thermally-assisted light emission.

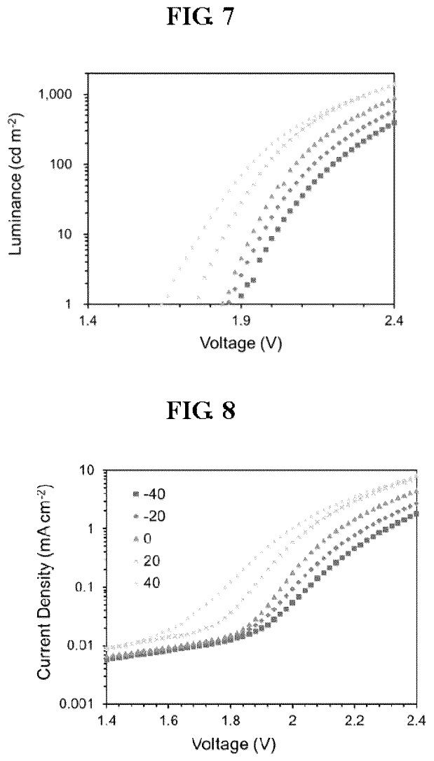

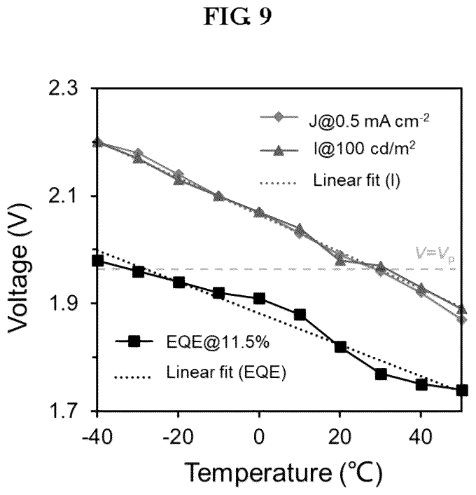

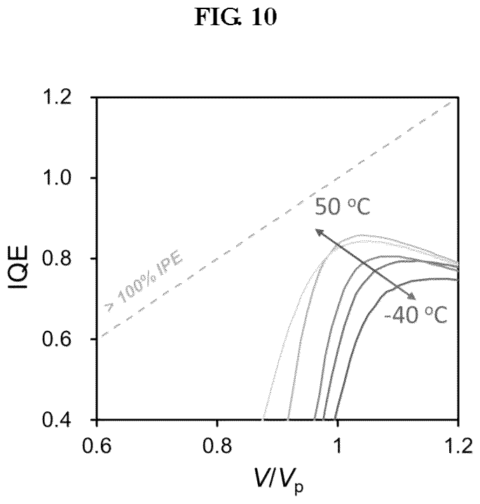

In QLEDs prepared with solution-based methods, sub-bandgap electroluminescence (EL) was often observed. Existing technologies generally attribute this to Auger-mediated hole injection rather than thermoelectric pumping. In the proposed Auger process, one or more pairs of electrons and holes recombine at the interface between the quantum dot layer and the electron/hole injection layer to facilitate the entry of a third free carrier into the emission layer. Subsequently, electron-hole radiative recombination results in the emission of photons with bandgap energy. In summary, two pairs of carriers are annihilated to emit one photon, setting the IQE upper limit for Auger-mediated processes at 50%. However, the IQE of the device in Example 1 is greater than 90% at 1.86 V, thus demonstrating that sub-bandgap EL is not achieved through the Auger-mediated charge injection. The operating mechanism of TEP-LEDs relies on thermally assisted charge diffusion at the hetero-junction(s) by absorbing lattice phonons. Thus, a temperature-enhanced EQE at a given voltage should be expected. FIG. 6 clearly shows that, at a given bias voltage, EQE of a device increases sharply upon increasing the operating temperature from −40 to 50° C. Results (FIG. 7 & FIG. 8) further show that such temperature-enhancement occurs for both current and brightness. FIG. 9 illustrates that, at a given EQE (11.5%), Vₚ/V steadily increases from 99% at −40° C. to 112% at 50° C., indicating enhanced contribution of Peltier heat to electroluminescence upon increasing temperature. For typical GaN LEDs, the rate of SRH-type recombination is known to increase with operating temperature, which results in a leftward and downward shift of their IQE versus forward voltage upon increasing operating temperature. Because of QD's practically defect-free nature, the IQE curves of TEP-QLEDs shifts in an ideal manner (FIG. 10), i.e., leftward and upward, which results in significantly increased EPE of the device at a certain brightness level.

### Example 2

Example 2 differs from Example 1 in that the QD solution has a QD concentration of 15 mg/mL. The quantum dot layer has a thickness of 2 monolayers, and the QD solution is an octane solution of CdSe/CdSeS/ZnS produced by Najing Technology Corporation, with a quantum dot PL peak wavelength of 625 nm and an FWHM of 23.5 nm.

### Example 3

Example 3 differs from Example 2 in that the QD solution has a QD concentration of 20 mg/mL. The quantum dot layer has a thickness of 3 monolayers.

### Example 4

Example 4 differs from Example 2 in that the QD solution has a QD concentration of 24 mg/mL. The quantum dot layer has a thickness of 4 monolayers.

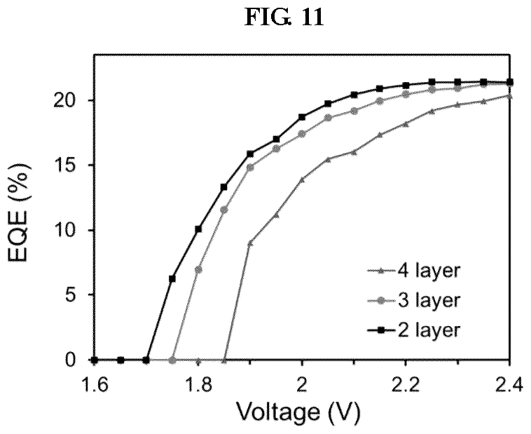

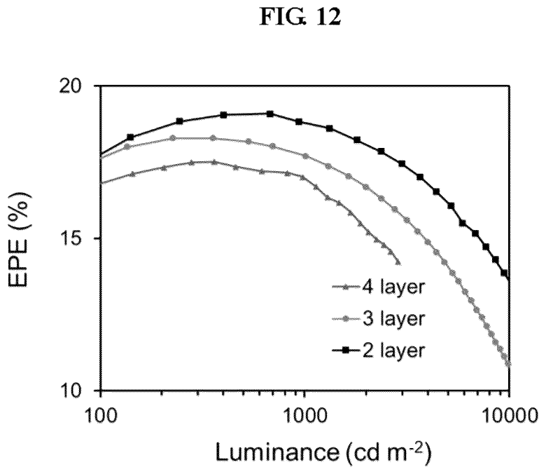

In FIG. 11, the thickness of the quantum dot layer is reduced from 4 monolayers to 2 monolayers, and the operating voltage decreases by 0.15 V In FIG. 12, the QLED device with a quantum dot layer thickness of 2 monolayers has the highest EPE within a luminance range of 100 cd/m² to 10,000 cd/m².

In summary, high-quality quantum dots can provide nearly 100% fluorescence quantum yield for up-conversion EL excited under mild conditions, such that TEP-QLEDs have nearly 100% IPE. LEE can be improved through light extraction techniques. Therefore, high-luminance TEP-QLEDs can be obtained for illumination or display devices. Given that TEP-QLEDs have near 100% IQE at low carrier densities, it may be possible to achieve EL cooling devices in the future. The cooling effect stabilizes the quantum dot layer and charge transport layer in the device.

The foregoing is merely illustrative of the preferred embodiments of the present application and is not intended to limit the present application, and various changes and modifications can be made to the present application by those skilled in the art. Any modifications, equivalent replacements, improvements, etc., made within the spirit and principle of the present application shall be included within the protection scope of the present application.

1. A light-emitting device, comprising at least one quantum dot LED, wherein the quantum dot LED comprises a first electrode, an electron transport layer, a quantum dot layer, a hole transport layer, and a second electrode which are sequentially stacked; a fluorescence quantum yield of quantum dots in the quantum dot layer is equal to or greater than 50%; a ratio of an average photon voltage to an operating voltage of the quantum dot LED is equal to or greater than 1; electroluminescence of the quantum dot LED comprises thermoelectrically-assisted up-conversion luminescence.

2. The light-emitting device according to claim 1, wherein the operating voltage equals the average photon voltage, and over 50% of the electroluminescence in the quantum dot LED is thermoelectrically-assisted up-conversion luminescence.

3. The light-emitting device according to claim 1, wherein the quantum dot layer comprises red quantum dots, the operating voltage is 1.86 V, and over 90% of the electroluminescence in the quantum dot LED is thermoelectrically-assisted up-conversion luminescence.

4. The light-emitting device according to claim 1, wherein the quantum dots in the quantum dot layer are free of internal lattice defects, and the quantum dots have no surface trap luminescence; the quantum dots in the quantum dot layer present non-blinking fluorescence and present a fluorescence quantum yield of over 90%.

5. The light-emitting device according to claim 1, wherein the quantum dot layer has a thickness of 1 to 2 monolayers of quantum dots.

6. The light-emitting device according to claim 1, wherein the electron transport layer comprises a ZnMgO nanocrystal layer, and the hole transport layer comprises a PVK layer, a Poly-TPD layer, and a PEDOT: PSS layer which are sequentially arranged; the first electrode is a silver electrode, and the second electrode is an ITO electrode.

7. The light-emitting device according to claim 1, wherein the quantum dots in the quantum dot layer are CdSe/CdS core-shell quantum dots or CdSe/CdSeS/ZnS core-shell quantum dots.

8. The light-emitting device according to claim 1, wherein the ratio of the average photon voltage to the operating voltage is less than 2.

9. The light-emitting device according to claim 1, wherein an operating temperature of the quantum dot LED is −40° C. to 50° C., and an external quantum efficiency of the quantum dot LED increases as the operating temperature rises.

10. The light-emitting device according to claim 1, wherein the operating voltage of the quantum dot LED is lower than the average photon voltage by 0.05 V to 0.2 V.

11. The light-emitting device according to claim 1, wherein under operating conditions at 100 cd/m2, an internal power efficiency of the quantum dot LED is equal to or greater than 90%.

12. The light-emitting device according to claim 1, wherein an external power conversion efficiency of the quantum dot LED is equal to or greater than 20%.

13. The light-emitting device according to claim 1, wherein an internal quantum efficiency of the quantum dot LED is equal to or greater than 90%.

14. The light-emitting device according to claim 1, wherein the quantum dot LED is prepared using a solution-based method.

15. The light-emitting device according to claim 1, wherein the light-emitting device is an illumination device or a display device; the quantum dot LED comprises quantum dot LEDs with various emitting wave bands, an operating voltage of each of the quantum dot LEDs is independently controlled, and a ratio of an average photon voltage to a corresponding operating voltage of each of the quantum dot LEDs is equal to or greater than 1.

16. A method for using quantum dot LEDs, wherein the quantum dot LED comprises a first electrode, an electron transport layer, a quantum dot layer, a hole transport layer, and a second electrode which are sequentially stacked; a fluorescence quantum yield of quantum dots in the quantum dot layer is equal to or greater than 85%, making a ratio of an average photon voltage to an operating voltage of each of the quantum dot LEDs equal to or greater than 1; electroluminescence of the quantum dot LED comprises thermoelectrically-assisted up-conversion luminescence.

17. The light-emitting device according to claim 2, wherein under operating conditions at 100 cd/m², an internal power efficiency of the quantum dot LED is equal to or greater than 90%.

18. The light-emitting device according to claim 3, wherein under operating conditions at 100 cd/m², an internal power efficiency of the quantum dot LED is equal to or greater than 90%.

19. The light-emitting device according to claim 4, wherein under operating conditions at 100 cd/m², an internal power efficiency of the quantum dot LED is equal to or greater than 90%.

20. The light-emitting device according to claim 5, wherein under operating conditions at 100 cd/m², an internal power efficiency of the quantum dot LED is equal to or greater than 90%.
